(19) United States
(12) Patent Application Publication
(10) Pub. No.: US 2026/0170189 A1
(43) Pub. Date: Jun. 18, 2026

(54) METHODS CIRCUITS DEVICES SYSTEMS AND FUNCTIONALLY ASSOCIATED MACHINE EXECUTABLE INSTRUCTIONS TO GENERATE A SEATING PLAN FOR AN EVENT TO BE HELD WITHIN A VENUE

(71) Applicant: Wix.com Ltd, Tel Aviv (IL)

(72) Inventors: Donatas DAUTARTAS, Vilnius (LT); Vytenis URBONAVICIUS, Vilnius (LT); Shai HOSHKOVER, Tel Aviv (IL)

(21) Appl. No.: 18/439,545

(22) Filed: Feb. 12, 2024

Related U.S. Application Data
(60) Provisional application No. 63/484,597, filed on Feb. 13, 2023.

(51) Int. Cl. G06F 30/13; G06Q 10/02

(52) U.S. Cl. CPC G06F 30/13; G06Q 10/028

(57) ABSTRACT

Disclosed are methods, circuits, devices, systems, and functionally associated machine executable instructions for generating a seating plan for an event at specific venue. According to embodiments, a system input receives one or more representations of the venue, which representation may include information about venue layout, structure elements and existing seating. A seating plan generator module fact factor information within the received representation along with use preferences to propose one or more seating plans. Optionally, computer vision is used to extract features from the representation. Portions of one or more reference seating plans may be utilized as templates when generating a proposed seating plan. One or more object placement and or path routing algorithms may be utilized when generating one or more proposed seating plans.

### FIELD OF THE INVENTION

The present invention relates generally to the field of computed aided design, artificial intelligence and digital communication. More specifically, the present invention relates to methods, circuits, devices, systems, and functionally associated machine executable instructions to generate a seating plan for an event to be held within a venue.

### CROSS REFERENCE TO RELATED APPLICATIONS

This application claims the benefit of priority of US Provisional Patent Application No. 63/484,597, filed on Feb. 13, 2023, which is incorporated herein by reference in its entirety.

### BACKGROUND

Civic, social, entertainment and various other types of gatherings, including for examples meetings, conferences, shows, concerts and other types of organized events where groups of people must be managed in terms of movements and organized in terms of seating have always been challenging to plan and orchestrate. Numerous factors, controllable and otherwise, impact on the execution of almost every aspect of every event, positively and negatively.

The evolution of the Internet and of related information technologies in general has smoothed out some of the aspects of organizing and executing a specific event in specific venues. Aspects of event management already addressed by today's technology include ticket generation, sales and distribution. Purely online aspects of such events are relatively straightforward to handle using websites and e-commerce mechanisms. And even though some events have even completely migrated to purely online formats, the vast majority of events are physical in nature and include venue related physical aspects needing digital analogs or representation in order to benefit from computer assistance in with organization and internet assistance with marketing and sale.

In the connection with publishing already digitized data relating to events and venues, various tools, including the applicant's own website building platform already exist. Website building systems (WBS) are used by both novices and professionals to create interactive websites. Existing WBSs are based on a visual editing model and most WBSs typically provide multiple templates, with a template possibly including a complete sample website, a website section, a single page or a section of a page.

WBS users (also known as designers, subscribers, subscribing users or site editors) may design the website and the website's end-users (the “users of users”) may access the websites created by the users. Although end-users typically access the system in read-only mode, WBSs (and websites) may allow end-users to perform changes to the web site such as adding or editing data records, adding talkbacks to news articles, adding blog entries to blogs etc. The WBS may in fact allow multiple levels of users (i.e., more than two levels), and assign different permissions and capabilities to each level. Users of the WBS (in particular in the full or partial on-line configurations described below) may register in the WBS server which manages the users, their web sites and accesses by the end-users.

A WBS may be a standalone system or may be embedded inside a larger content generation or editing system. It may also be on-line (i.e., applications are edited and stored on a server), off-line or partially on-line (with web sites being edited locally but uploaded to a central server for publishing). The WBS may use an internal data architecture to store WBS based sites and this architecture may organize the handled sites' internal data and elements inside the system. This architecture may be different from the external view of the site (as seen, for example, by the end-users). It is also typically different from the way the HTML pages sent to the browser are organized.

For example, the internal data architecture may contain additional properties for each element in the page (creator, creation time, access permissions, link to templates, SEO (search engine optimization) related information etc.) which are relevant for the editing and maintenance of the site in the WBS, but are not externally visible to end-users (or even to some editing users). The WBS may implement some of its functionality (including both editing and run-time functionality) on a server or server set, and some of its functionality on client elements. The WBS may also determine dynamically whether to perform some functionality on the server or on the client platform.

A WBS typically handles the creation and editing of visually designed applications (such as a website) consisting of pages, containers and components. Pages may be separately displayed and contain components. Components may include containers as well as atomic components. Reference is made to FIG. 1A, which is a schematic block-diagram illustration of a website building system (WBS) 2 which may be used for building a website 3, in accordance with some demonstrative embodiments of the present invention. WBS 2 may be used to build, produce, edit and/or generate website 3, which may comprise pages 4 which may include components 5 (e.g., text, images, videos and background/non-display components).

The WBS may also support hierarchical arrangements of components using atomic components (text, image, shape, video etc.) as well as various types of container components which contain other components (e.g., regular containers, single-page containers, multi-page containers, gallery containers etc.). The sub-pages contained inside a container component are referred to as mini-pages, and each of which may contain multiple components. Some container components may display just one of the mini-pages at a time, while others may display multiple mini-pages simultaneously, some may not display sub-elements at all.

The components may be contentless or have internal content. An example of the first category is a star-shape component, which does not have any internal content (though it has color, size, position, attributes and other parameters). An example of the second category is a text paragraph component, whose internal content includes the internal text as well as font, formatting and layout information (which is also part of the content rather than being attributes of the component). This content may, of course, vary from one instance of the text paragraph component to another. Components that have content are often referred to as fields (e.g., a “text field”).

Pages may use templates, general page templates or component templates. Specific cases for templates include the use of an application master page containing components replicated in all other regular pages, and the use of an application header or footer (which repeat on all pages). Templates may be used for the complete page or for page sections. The WBS may provide inheritance between templates, pages or components, possibly including multi-level inheritance, multiple inheritance and diamond inheritance (i.e., A inherits from B and C and both B and C inherit from D).

The visual arrangement of components inside a page is called a layout. The WBS may also support dynamic layout processing, a process whereby the editing of a given component (or other changes affecting it such as externally-driven content change) may affect other components, as further described in U.S. Pat. No. 10,185,703 entitled “Website Design System Integrating Dynamic Layout and Dynamic Content” granted 22 Jan. 2019, commonly owned by the Applicant, and incorporated herein by reference.

A WBS may be extended using add-on applications such as a third party application and its components, list applications (such as discussed in US Patent Publication No. US 2014/0282218 entitled “WBS Integrating Data Lists with Dynamic Customization and Adaptation” published 18 Sep. 2014, commonly owned by the Applicant and incorporated herein by reference.) and WBS configurable applications (such as described in in U.S. patent publication Ser. No. 16/683,338 entitled “System And Method for Creation and Handling of Configurable Applications for Website Building Systems” filed 14 Nov. 2019 commonly owned by the Applicant and incorporated herein by reference. These third-party applications and list applications may be added and integrated into designed websites.

Such third-party applications and list applications may be purchased (or otherwise acquired) through a number of distribution mechanisms, such as being pre-included in the WBS design environment, from an Application Store (integrated into the WBS's market store or external to it) or directly from the third-party application vendor.

The third-party application may be hosted on the WBS vendor's own servers, the third-party application vendor's server or on a 4th party server infrastructure.

The WBS may also allow procedural code to be added to some or all of the system's entities. Such code could be written in a standard language (such as JavaScript), an extended version of a standard language or a language proprietary to the specific WBS. The executed code may reference APIs provided by the WBS itself or external providers. The code may also reference internal constructs and objects of the WBS, such as pages, components and their attributes.

The procedural code elements may be activated via event triggers which may be associated with user activities (such as mouse move or click, page transition etc.), activities associated with other users (such as an underlying database or a specific database record being updated by another user), system events or other types of conditions.

The activated code may be executed inside the WBS's client element, on the server platform or by using a combination of the two or a dynamically determined execution platform. Such a system is described in US Patent Publication No. US 2018/0293323 entitled “System and Method for Smart Interaction Between Website Components” published 11 Oct. 2018, commonly owned by the Applicant and incorporated herein by reference.

Typical site creation may be based on a number of models, including a visual editing model (in which the user edits a previously created site) and an automatic site generation model or a combination thereof as illustrated in FIG. 2 to which reference is now made and is described in U.S. Pat. No. 10,073,923 entitled “System and Method for the Creation and Update of Hierarchical Websites Based on Collected Business Knowledge” granted 11 Sep. 2018, commonly owned by the Applicant and incorporated herein by reference.

It will be appreciated that throughout the specification, the acronym WBS may be used to represent a website building system. FIG. 1B illustrates a system 100 that comprises a typical WBS 2 in communication with client systems operated by WBS vendor staff 61, a site designer 62 (i.e., a user), a site user 63 (i.e., user of user) and with external systems 70. WBS 2 may further comprise a WBS site manager 10, an object marketplace 15, a WBS RT (runtime) server 20, a WBS editor 30, a site generator system 40 and a WBS content management system (CMS) 50. It will be appreciated that the elements of FIG. 1B may function as described in U.S. Pat. No. 10,073,923. FIG. 1B further illustrates a ticketing system 200 and a seating plan generator module 300 integrated into WBS 2.

In the visual editing model, the user (designer) edits a site based on one or more website templates. The WBS provider may provide multiple site (or other) templates, with each template possibly including a complete sample web site, a web site section, a single page or a section of a page. Users may have the option to start with an empty site (essentially a “blank page” template) but would typically start with an actual site template.

The WBS provider may provide site templates ranging from the very generic (e.g., mobile site, e-store) through the more specific (e.g., law office, restaurant, florist) to the highly specific ones (e.g., a commercial real-estate law office or a Spanish tapas restaurant). Such templates are typically stored in a repository accessible to users of the WBS and are typically classified according to business type, sub-type or industry. Templates may also be created (and classified) according to style, color range or other parameters and not just according to business type. Site templates may be extended with additional (typically back-end) functionality, services and code in order to become full-fledged vertical solutions integrated with the WBS.

Thus, the user's first experience when creating a site using a WBS visual editor may typically be that the user chooses a template (e.g., according to style or industry type/sub-type), possibly a blank template and then edits the template in the visual editor including the editing of content, logic, layout and attributes. Such editing may include (in particular) adapting the template and its elements to the details of the user's business. The user may then publish the modified site.

Under the site generation model, the WBS generates an initial site for the user, based on a selected template, possibly modified by filling-in common elements of information, and possibly allowing follow-up editing of the generated site. This filling-in is required as various pieces of information (such as the business name or a description of the management team) are included in multiple locations in the template's pages. Thus, the user may have to change the business name (for example) in multiple places throughout the template.

Furthermore, some template elements (e.g., a generic product page) may appear multiple times, with each instance displaying the details of a different instance of an underlying entity (e.g., different products offered in the site). Such multiple instances may be manually specified (e.g., the details of different persons in the company's management team) or dynamically derived from an external database (e.g., product details from the “products on sale” database). Such an arrangement is often known as a “repeater”.

The template may also include fields. For example, the WBS may allow the template designer to specify fields (also known as “placeholders”) for the insertion of values inside the templates, such as {Company Name}, {Product-Name}, {ProductPrice} etc. The user may also specify the values for the fields defined in the template selected for the website.

The WBS may allow the user to enter simple or complex values (e.g., text and images), as well as additional (non-field) information such as selection of included pages or web site areas, colors, style information, links, formatting options, website display options, decoration elements (such as borders and backgrounds) etc.

The WBS may also allow the user to enter some of this additional information before selecting a template and use this information to help in selecting a template (e.g., by narrowing the set of proposed templates). For example, the user may select a certain generic color scheme (e.g., pastel colors) or style (e.g., business/formal), and the system may then use this selection to narrow the set of proposed templates.

The system may also display a series of views or questionnaires to allow the user to enter values or selections (for both the defined fields and the additional information above). The system may further create a connection (or binding) between a multiple-instance element of the template (as described herein above) and an internal or external database which provides the data instances used to generate the displayed instances.

Once a template has been selected and its fields and additional information have been specified (e.g., through the questionnaires or through binding to data sources), the WBS may generate the website containing the combined information. The user may then publish the site (through the WBS or otherwise).

A WBS may perform semi-automatic site creation using a different model as described in U.S. Pat. No. 10,073,923. Under this model, the system gathers information on the user and his web site requirements from multiple sources which may include, for example: user-filled questionnaires; existing user presence (such as existing web sites or social media presence), industry sources (such as general trade web sites), off-line information and internal system repositories which provide information on specific business types, such as basic template information for specific business types (lawyers, restaurants, plumbers, graphic designers etc.), possibly refined for specific industries (e.g., distinguishing between real-estate lawyers and personal injury lawyers).

The system may also gather external information from other sites, both internal and external to the system. Such information may affect, for example, the selection of offered questionnaires and layout elements, proposed defaults etc. Such information may also typically be collected on a statistical or summary basis, in order not to expose information belonging to any single user, and protect users' privacy, anonymity and legal rights (such as copyrights). Such information may be located based on information provided by the user which may be direct (e.g., an existing website address) or indirect (a business name and geographical address which can be used to locate information about the business).

The gathered information is analyzed and arranged into a repository of content elements which are then mapped onto layout elements that present the content from the content elements and combine the layout elements to form the site. The layout element mapping, selection and combination process may be fully automatic or semi-automatic (i.e., including user interaction).

To support the above-mentioned functionality, a WBS will typically maintain a series of repositories, stored over one or more servers or server farms. Such repositories may typically include various related repositories such as a user information/profile repository, a WBS (WBS) component repository, a WBS site repository, a Business Intelligence (BI) repository, an editing history repository, a third-party application store repository, etc. The system may also include site/content creation related repositories such as a questionnaire type repository, a content element type repository, a layout element type repository, a design kit repository, a filled questionnaires repository, a content element repository, a layout element repository, a rules repository, a family/industry repository etc. A description of these repositories may be found in U.S. Pat. No. 10,073,923.

Responsive editing for web design is known in the art. In an age of creating and viewing websites on different sized viewports such as personal computers, tablets and mobile communication devices (all of which themselves have different screens displays and windows with different viewing dimensions), responsive editing allows for the rendering of a single web page on a variety of devices and window or screen sizes. It will be appreciated that websites may be responsive i.e., may change their design when viewed and may be supported by a responsive editor. Alternatively, some systems may support the functionality of a responsive site without the use of a responsive editor. Thus content, design and performance are maintained across all devices and platforms to ensure usability and satisfaction.

A site designed to comply with responsive editing typically adapts the layout to the viewing environment by using mechanisms such as proportion-based grids which allow for page element sizing in relative units such as percentages rather than absolute units such as pixels or points. Elements may be docked onto the page and break-points may be defined to designate at what point a website page's content and design needs to be adapted in a noncontinuous manner to meet the different viewport sizes. The breakpoints define the specific width points where the web-page should use a different layout or arrangement of com-ponents accordingly (rather than modifying the design in a continuous manner).

There are many ways to implement responsive web sites (both for viewing and editing). For example, responsive site behavior can be implemented:

On the server side, e.g., through pre-processing or adapting the page definition for a given target device or width.

On the client side, using JavaScript (or any other browser-based language) to process page width or other target characteristics parameters or changes.

On the client side, using CSS (cascading style sheets), or any other mark-up, presentation or style definition language which provide device, platform or display information querying and the ability to create declarative style definitions based on characteristics of the target device or display. Such declarative style definitions may be executed inside the browser's rendering engine, without requiring rendering external code to execute (such as JavaScript code).

As a user changes his viewport display (whether by changing his device or display window), the website should automatically switch to accommodate resolution, viewports size and scripting abilities by any (or a combination) of the methods above.

### Integrating Events and Venues:

One of the vertical solutions which may be integrated with the WBS is a solution for the management of events and venues. This may include functionalities like venue setup, event management, ticket ordering and provisioning, seat assignment, and related functions.

To be in line with the ease of use provided by the WBS to its users (e.g., when creating their sites), such an events vertical may employ a system as described herein for the easy design and setup of venues and entry of the venues' seating arrangement.

Tools for efficiently and quickly planning, digitizing and publishing physical aspects, such as seating arrangement or plans, for an upcoming event at a specific venue are, however, lacking. This fact can be at least partially explained by the complexity of arranging seating for large numbers of event participants in dynamically configurable venues characterized by combinations of fixed and dynamic physical features. Simple planning algorithms and space digitizing devices of the prior art have had limited impact in regard to speeding up and enhancing the publication of upcoming events to the internet due to the complexity associated with optimizing a seating plan around existing venue features such as existing seating, stage location, structural support and bathroom placement, etc.

There are numerous logistical factors that must be addressed when arranging seating for a specific event within a large event venue or concert hall:

Capacity: The venue must be able to accommodate the expected number of attendees. This requires careful calculation of the number of seats available and ensuring that there is enough space for all attendees to comfortably sit.

Safety: The seating arrangement must adhere to safety regulations and guidelines to ensure the safety of attendees. This includes ensuring that there is enough space between rows and seats, and that aisles are wide enough for emergency exits.

Accessibility: The venue must be accessible for attendees with disabilities. This includes ensuring that there are designated seating areas for attendees who require wheelchair access, as well as providing ramps and other necessary accommodations.

Ticketing: The venue must have a system in place for managing ticket sales and distributing seating assignments. This can involve working with ticketing companies and implementing ticket scanning systems at the entrance to the venue.

Crowd control: The seating arrangement must be designed to help manage crowds and ensure that attendees can enter and exit the venue safely and efficiently. This may involve creating designated areas for different ticket types or implementing a system for directing attendees to their seats.

Sightlines: The seating arrangement must be designed to ensure that all attendees have a clear view of the stage or event area, as well as acceptable (or better) sound quality. This may involve creating tiered seating or using screens to provide a view for attendees who are seated farther back.

Comfort: The seating arrangement must be comfortable for attendees, particularly for events that are expected to last for several hours. This may involve providing cushioned seats or offering additional amenities such as cup holders or armrests.

Acoustics: the seating arrangement may take into account the acoustics of different parts of the venue. This may involve placement of additional speakers or other means to prevent better audio experience across the different seats in the venue.

Designing event related seating plans, while factoring all of the above, along with existing venue infrastructure features, to design a seating plan for the specific event within the specific venue is usually manually performed by one or a group of people with experience in the process. Digitizing and publishing these plans to a website is another step, often performed by another one or more persons. Integration of the seating plan into a ticket purchase system, which system may or may not be accessible online, is may be performed by yet other people.

The process of designing and publishing web ticketing system usable seating plans for new events at specific existing venues is complex and time consuming. Integration of newly designed seating plans into ticketing system, online or not, remains a challenge each time a new design is conceived. There remain needs for improved methods and technologies for designing, generating, publishing and otherwise commercializing seating plans for an event, new or otherwise, at venues which may or may not include preexisting constraints on seating placement, layout and volume.

### INCORPORATED REFERENCES

This present patent application makes reference to the following patent applications, all of which were filed by the common assignee of this patent application and all of which are hereby incorporated by reference in their entirety:

| Name | Appl. No. | Filled | Publication No. |
|---|---|---|---|
| DL | 13/771,119 | 20 Feb. 2013 | US 2013-0219263 |
| LA | 14/207,761 | 13 Mar. 2014 | US 2014-0282218 |
| MAC | 14/483,981 | 11 Sep. 2014 | US 2015-0074516 |
| ML | 14/699,828 | 29 Apr. 2015 | US 2015-0310124 |
| ACE | 15/175,272 | 7 Jun. 2016 | US 2016-0357527 |
| SE | 15/292,172 | 13 Oct. 2016 | US 2017-0046317 |
| MLX | 16/000,907 | 6 Jun. 2018 | US 2018-0300361 |
| OB | 16/120,324 | 3 Sep. 2018 | US 2018-0373799 |
| CBF | 16/044,461 | 24 Jul. 2018 | US 2019-0026083 |
| EOH | 16/266,197 | 4 Feb. 2019 | US 2019-0243882 |

### SUMMARY OF THE INVENTION

The present invention may include methods, circuits, devices, systems along with functionally associated machine executable instructions for generating a seating plan for an event held within a venue. A system according to embodiments of the present invention may be configured for generating a digital seating plan for a given event in a given venue and may include an input module that receives and analyzes a visual representation of the venue. The visual representation may be a vectorized or a raw (non-vectorized) representation such as a handwritten sketch, video recording, or photograph of the venue. The system may also include a Seating Plan Generator Module (SPGM) that uses one or more algorithms to autogenerate a seating plan based on physical constraints identified within the visual representation and user-selected priorities. The SPGM may be functionally associated with a Venue Feature Classifier (VFC) that identifies and registers features of the venue such as fixed columns, existing seats, and stages or platforms. The SPGM may generate seat identifiers for existing seats and new seat proposals with corresponding location coordinates. The system and its constituent components may be integrated with an event ticketing system to allow for public purchase of tickets. The system may also be integral or functionally associated with an online website builder which may be used to generate event related websites with seat specific ticket purchasing capabilities.

According to embodiments, a system input receives one or more representations of the venue, which representation may include information about venue layout, structural elements and existing seating. A seating plan generator module may factor information within the received venue representation, such as one or more image, along with user preferences to generate and propose one or more seating plans. Optionally, computer vision may be used to extract features from the venue representation. Portions of one or more reference seating plans may be utilized as templates when generating a proposed seating plan. One or more object placement and or path routing algorithms may be utilized when generating one or more proposed seating plans.

An event seat planning system according to embodiments may utilize computer vision and computer vision-based image feature extraction to efficiently create and manage seating arrangements for events. The system can receive some representation of a venue within which the event is to be held, usually a non-vectorized (e.g., not CAD) representation such as a hand drawing or photos of the venue, which is then processed with a computer vision system to extract venue related features.

Computer Vision may be used to analyze and understand raw images and also vectorized images. The incorporation of AI into Computer Vision has had a significant impact on research, patents, and products, and is even offered as a service by various cloud-based services. In the event management industry today, computer vision technologies are already commonly used in identification processes and real-time crowd analysis. They are also integrated into virtual reality systems such as head-mounted displays for VR and AR applications.

In the context of the present invention, computer vision may be utilized to understand drawings, classify image types, read 2D floor plans and create 3D models, and create digital twins for purposes of generating and publishing seating plans within the context of a digitized/virtual version of the venue.

As events and concerts have become more dynamic, with more pop-up events and changing venue plans, the process of planning new venues has become increasingly complex. Furthermore, having more pop-up concerts and events, means venue plans are changing on a regular basis.

Therefore, the event seat planning system of the present invention presents a novel solution for efficiently creating and managing seating arrangements for events, optionally within a Website Building System (WBS). According to these embodiments, computer vision and computer vision-based feature extraction may be used as a starting point to generate one or more seating plans based on an image of the venue.

The system may begin by using Computer Vision to recognize and extract relevant venue information from one or more images of the venue, such as the dimensions and layout of the venue, the locations of existing seating and structural features, and any other relevant details. This information may then be analyzed and used to generate a seating plan that takes into consideration the existing seating and structural features of the venue. The generated seating plan may then be provided to an event ticketing system that is integral or otherwise associated with the WBS, allowing for the easy management and sale.

The seating plan generator according to embodiments is also able to design a seating plan by generating several proposals based on the relevant information extracted from the image and interacting with the user to converge on a finalized plan. The system may begin by using Computer Vision to recognize and extract relevant information from an image representation of the venue. Feature extraction may extract features including dimensions and layout of the venue, the locations of existing seating and structural elements, and any other relevant details. The generator may then use the extracted information in combination with seating parameter preferences provided by the user, explicitly or implicitly, to generate multiple seating plan proposals and presents them to the user for review and feedback. The user can then provide input and make changes to the proposals, and the generator will iteratively refine the plans until a final plan is agreed upon.

One source of generated proposals from the system may be template seating plans, or portions of temple seating plans, generated from seating plans of pervious events at the same venue, assuming no change in the venue infrastructure features has occurred. Optimized placement and routing algorithms, one or more of each, may augment or replace use of the templates.

The generated seating plan proposals can then be provided to an event ticketing system that is integral or otherwise associated with the WBS, allowing for the easy management and sale of tickets for the event. One of the main advantages of using the seat planning system within a WBS context is the built-in ability to understand the profiles and traits of the user and their site users (UoU). By studying user behavior such as mouse movements, color choices, web design considerations, and eye movement, the system can determine user personality traits and preferences or aversion toward risk, decisiveness, and conservatism. This information can then be used to refine suggestions and predictions for seating arrangements based on the user's personality traits, either through a rule-based system or machine learning. For example, a risk-averse user might be offered a relatively more conservative seating arrangement with relatively low-density seating and numerous comfort and safety features designed into the arrangement. The opposite might be proposed to a user whose preferences lean towards a larger number of seats with less emphasis on comfort and safety.

Throughout the present application, the terms “seat plan” and “seating plan” are used interchangeably. Both are meant to describe a plan or arrangement of seats throughout a venue, without specific association of specific persons to utilize the specific seats.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A is a block diagram of software layers of an event seating plan generator integrated with a WSB and an event ticketing system;

FIG. 1B is a functional network diagram of a seating plan generator module integrated with a WBS and with an event ticking system;

FIG. 2A is an overhead image of an exemplary venue which could be serviced by a system in accordance with embodiments of the present invention;

FIG. 2B is a flow chart of an exemplary method by which a system in accordance with embodiments of the present invention generates one or more proposed seating plans for a venue based on images of the venue such as shown in image 2A;

FIG. 2C is an edge detected version of the image of FIG. 2A which is processed by AI classifiers and grouping algorithms according to embodiments of the present invention;

FIG. 2D is an illustration the output of an embodiment of the present invention, the original representation labeled with seat plan related labels designating seat rows;

FIGS. 3A and 3B are screen shots from a venue representation generation screen and according to embodiments where the system is embedded or otherwise accessible to a WSB system;

FIG. 3C is an exemplary vectorized venue representation generated in accordance with embodiments of the present invention;

FIGS. 4A to 4C illustrates screens associated with uploading of a venue representation and or templates for use in developing a venue seating plan for a specific event;

FIG. 4D illustrates a proposed seating plan generated in accordance with embodiments of the present invention.

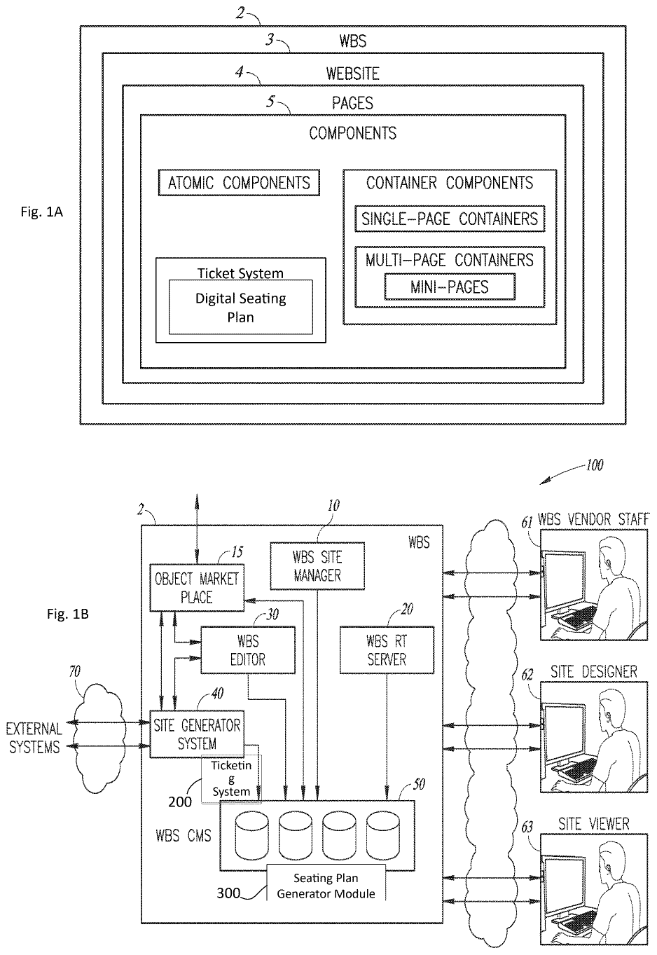

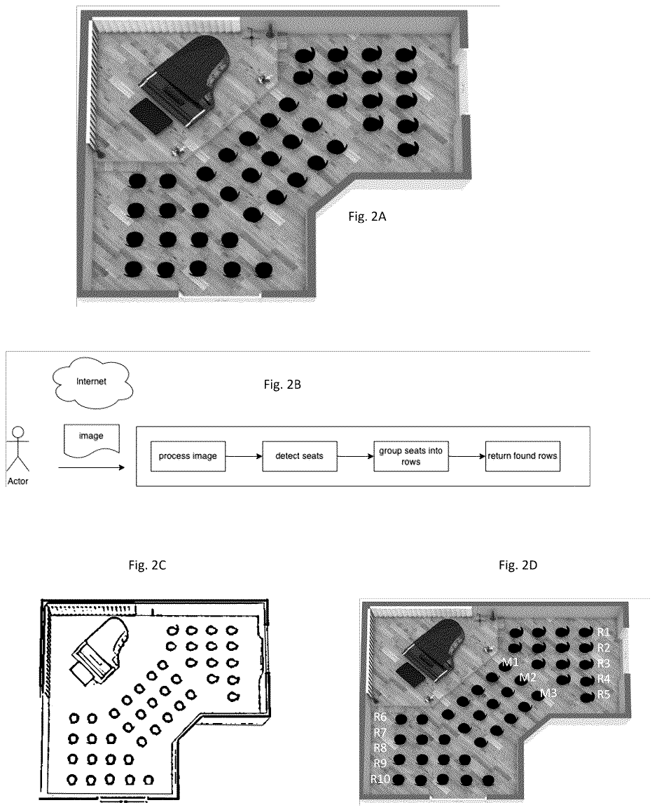

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Unless specifically stated otherwise, as apparent from the following discussions, it is appreciated that throughout the specification discussions utilizing terms such as “processing”, “computing”, “calculating”, “determining”, or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. This apparatus may be specially constructed for the desired purposes, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, magnetic-optical disks, read-only memories (ROMs), random access memories (RAMs) electrically programmable read-only memories (EPROMs), electrically erasable and programmable read only memories (EEPROMs), magnetic or optical cards, or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the inventions as described herein.

The processes and technologies described herein generally relate to website production and or editing within the context of live event planning and execution within selected venues. While responsive editing systems of the prior art, typically work at the website or page level, having predefined fixed breakpoints for sizing a website, enabling responsive editing on a limited number of viewports (including screens, displays and windows). It will be appreciated that when a site is changed (such as components changing size or position), the changes are continuous between break-points (within a single breakpoint range). When a breakpoint is crossed, non-continuous changes may occur, and components may jump from one position to another (e.g., component A may move above component B instead of side by side when the screen width shrinks.) Components may also appear and disappear when a breakpoint is crossed.

Applicant has realized that if the web designer has full control of his breakpoints, i.e., he can define his own ranges, he is able to effectively design websites with the knowledge of which breakpoint range sizes may be handled in a continuous manner and which are handled by altering the design in order to display his website over a larger range of viewports. This may enable the user to create and handle multi-size sites more effectively.

Furthermore, Applicant has realized that a responsive editor suited to a hierarchical component-based system i.e., handle functionality at the component level may ensure that breakpoints may be handled not only at the page level, but also at the presets level as well as the container level (e.g., using responsive editing grids at the container com-ponent level for the docking of its sub-elements) together with any implemented hierarchy. Thus, the designer's ability to define his own breakpoint ranges may give the designer fuller control over his media such as switching the use of an image from “background” to “floating”, the ability to apply multiple focal points (one per each break point) and the ability to provide different cropping parameters per break-point range.

Applicant has further realized that responsive editing components may be considered fluid and therefore be responsive to dynamic layout triggers and events that may occur during website editing. A layout may incorporate fluid components whose size and attributes may be affected by their parents (e.g., by parent changes or viewport width changes) or by additional triggers. The effects could be automatically determined by the system and may also be specified or edited by the user (e.g., the component width is a given percentage or function of the parent component width).

Applicant has also realized that the use of machine learning (ML) and artificial intelligence (AI) techniques and models to facilitate aspects of the user's work may also be integrated into a responsive editing system as described herein above, such as an understanding of how the user works in order to automatically adapt his layout to best fit all breakpoints. This may involve a system offering sections and components by understanding and detecting user intent. The system may employ a number of ML/AI engines to achieve its goals using the information available in the WBS such as website component information, business information, editing history and other site related information as well as WBS-based training feedback as described in the U.S. patent application Ser. No. 16/878,831 entitled “System and Method for Integrating User Feedback into Website Building System Services” filed on 20 May 2020, commonly owned by the Applicant and incorporated herein by reference.

Applicant has further realized that the application of rule-based and ML/AI engines may also be used to provide complete design expression capabilities where the system translates drag and drop designs into full CSS and understands the best fit locations for breakpoints. This may also include packaged layouts that support responsive design and fluid components and can further adapt to the break-points of the target design. Thus, responsive editing functionality may be combined with the website building system process as described in the background and the layout elements described may be adapted in order to build a responsive site.

Furthermore, Applicant has also realized that the abovementioned functionality may also be applied to existing nonresponsive websites (i.e., those without breakpoints) if they are converted or rendered to a smart mesh form which may also be implemented efficiently on web browsers and other client systems. This capability may be applied to existing WBS sites, or to sites imported from other systems. The smart mesh structure may therefore be used to define a site (with responsiveness and fluidity) declaratively. In this way, browsers may respond to changes in the width (as an example) inside the browser engine (e.g., as part of the CSS processing and display rendering). The process may provide inference and analysis for effective dynamic layout operations based on analysis of WBS component properties (geometrical/non-geometrical) and accumulated information (such as editing history and collected BI) tasks such as group detection and anchor generation.

Embodiments of the present invention also pertains to event management systems, particularly those utilized in or with Website Building Systems (WBS's) for constructing event and venue specific interactive websites with event ticket ordering functionality. Embodiments of the present invention may also be applied to other types of visual editing systems and various other scenarios and embodiments as further described below.

Further embodiments of the present invention may relate to novel techniques that integrate event planning related logistics with a WBS and its underlying repositories and user interface generation systems. Embodiments of the present invention may further leverage the extensive information available online to an WBS using data analysis functionality and machine learning to enhance capabilities of WBS users and their site users.

A system according to embodiments of the present invention may include or be functionally associated with a WBS which may be standalone, or which may be embedded inside a larger editing system. It may also be online (i.e., applications are edited and stored on a server or server set), offline, or partially online (with websites being edited locally but uploaded to a central server for publishing).

More specifically, embodiments of the present invention include solutions, systems, and frameworks for the creation of Event Venues plans (seating and others) which dramatically reduce the time needed to create a new venue for an event or concert. Optionally, these solutions to, systems and frameworks may be integral or otherwise associated with a WBS. Among the innovative features of the present invention is the use of OCR, ML, and other computer vision techniques to generate a vectorized representation of a venue, including its layout, structural features, seating and all other relevant features, starting with either a hand drawn or a computer aided drawing. According to some embodiments, venue layout information may be provided in printed or hand-sketched form and converted it into an editable data structure, which structure may be presented and edited on a screen of a system in accordance with embodiments of the present invention.

Additional aspects of the present invention include generating one or more seating plan proposals using AI and algorithms which factor the vectorized venue representation within the context of an event seating objective (e.g., number of seats to have available for event attendees) as constrained by structural and operational limitation of the venue and user's declared preferences for seating design. The use of AI and various routing algorithms can lead to the saving of critical time in providing extremely accurate complex venue plans or plan proposals, ready for execution or for digital manipulation by the user. When plan generation AI and algorithms are integral or otherwise functionally associated with an authoring system, such as a WBS, various seating arrangement preferences of the user may be obtained from previously declared and otherwise ascertained information about the user. Information about a subject and their preference may be provided by the subject, user or user's user, explicitly by asking the subject to complete a questionnaire forms. The information can also be inferred or derived by analyzing the subject's behavior during website authoring and or website browsing.

A specific advantage of implementing the present event venue seating plan generator within the context of a WBS, in accordance with embodiments of the present invention, is some level of access to a knowledgebase the WSB, with specific information about the user or user's users (UoU) of WBS. This information may be analyzed with the context of various psychological models to infer whether:
1. Is the user risk-averse or courageous?
2. Is the user decision making decisive or do they tend to change their minds?
3. Is the user's taste conservative or do they tend to be more flamboyant?

Various personality traits of a user can be identified while the user is defining and building her website, by monitoring their mouse moves, color choices, web design considerations, TPA choices, eye movement (or other biometrics markers or measures), etc. Understanding a user's traits enable the AI according to embodiment to generate create suggestions for a user and or to predict the future in the Events/Venue creation context. For example, when the system detects a risk-averse user, the venue seating suggestion would be moderate and solid, without featuring deviating from mainstream concepts for such events. For user's identified as more flamboyant, the system would tend to offer a more complex and modern venue plan. These user traits to suggestion mapping can be achieved AI/ML and rule-based algorithms or ML.

The system to be described with reference to the figures to follow include an event venue representation recognition engine implemented as a server-side application (though client-side or mixed implementations are possible as well). The application uses web protocols to communicate with one or more browser side clients. The server application accepts input images from the client and returns a collection of rows (seats are grouped in rows) or an empty collection if it does not find any seats in the image.

The process of generating a venue seating plan for an event starts with the client application being used to upload an image to the server application. The client may use the visual interface as a part of WBS or API to call the server directly. Once the image is successfully uploaded, the server application transforms the uploaded image in order to identify and vectorize the objects represented therein. It does so by using image processing and computer vision algorithms and image classification neural networks known today or to be devised in the future. The main steps performed in a vectorization according to embodiments of the present invention may include some or all of the following:
1) Apply High Pass Filter to edge detect features in the representation.
2) Apply Canny Edges Detection to remove Canny Edges
3) Apply Morphological operations: erosion and dilation
4) Thresholding with OTSU threshold. It is a variance-based technique to find the threshold value where the weighted variance between the foreground and background pixels is the least. Determined by minimizing intra-class intensity variance, or equivalently, by maximizing inter-class variance.

After the image transformation is complete, the server application runs a component-detection algorithm to find the seat objects in the transformed image.

After finding the points of the objects, the server application groups the points into rows, instead of individual seat objects. To do that, the application does 3 steps:
5) First step-detect all points with the same height value and fit line
6) Second step-multiple lines RANSAC (Random Sample Consensus) on the rest of the points
7) Third step-take care of leftovers if needed.

After all the steps are done, the server application returns the result in the form of main objects (rows) and their meta information:
Each row contains coordinates on a 2-dimensional grid (XY) that are relative to the uploaded image. The coordinates are required in order to keep the margins and layout of the rows.
Each row contains information about the number of seats in the row.

The resulting data structure should suffice the representation of the rows in a WBS in a similar manner. Identical representation cannot be guaranteed due to shape size and spacing differences between the original image and WBS settings.

Once the client application receives the response from the server application-a collection of rows—it adds each row one by one to the WBS screen, respecting the coordinates of the grid to maintain the layout and distancing between rows.

Using trained AI/ML the system finds similar venues and ask the user if her venue is the same. If yes, then we can skip some or all of the next image processing steps.

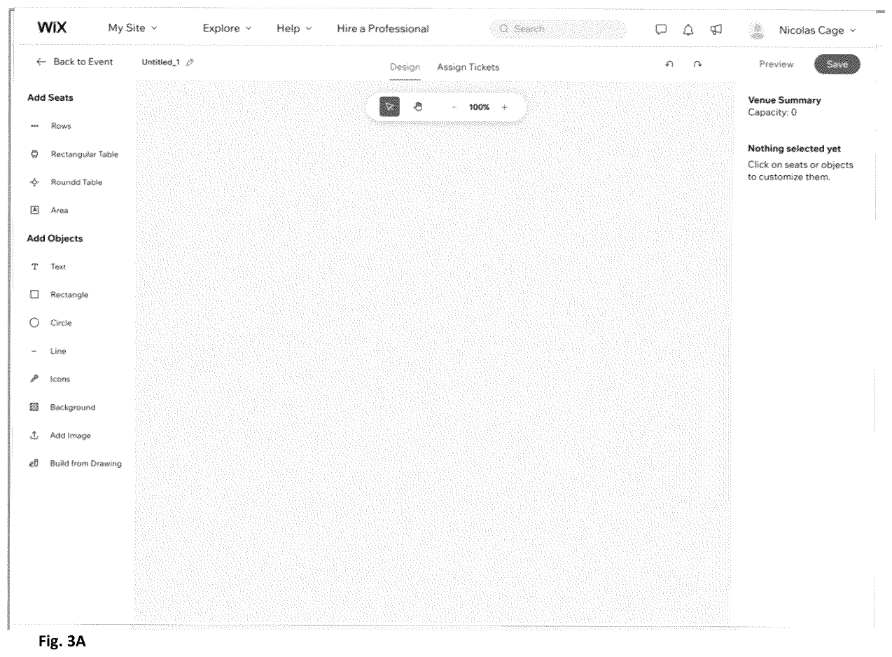

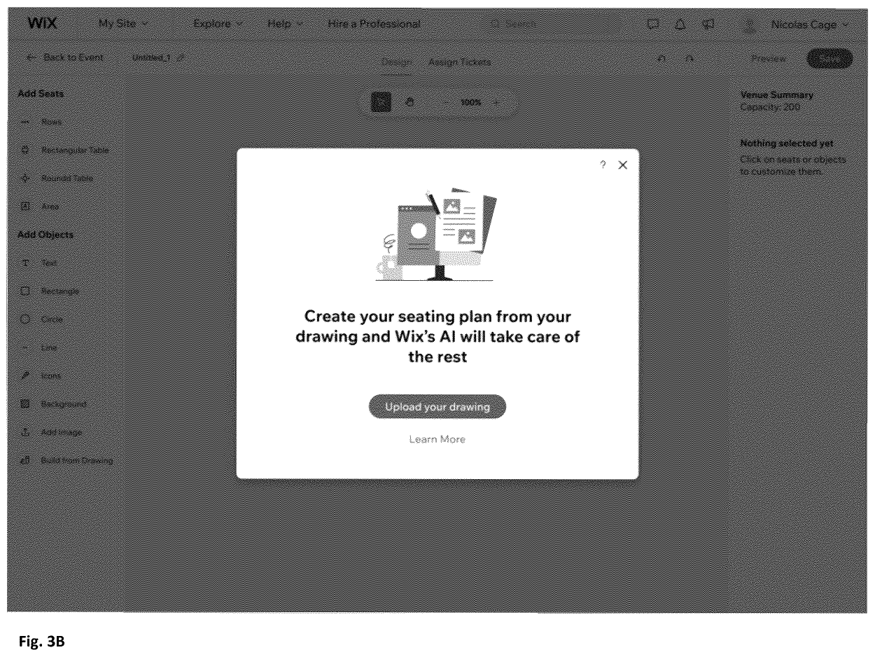

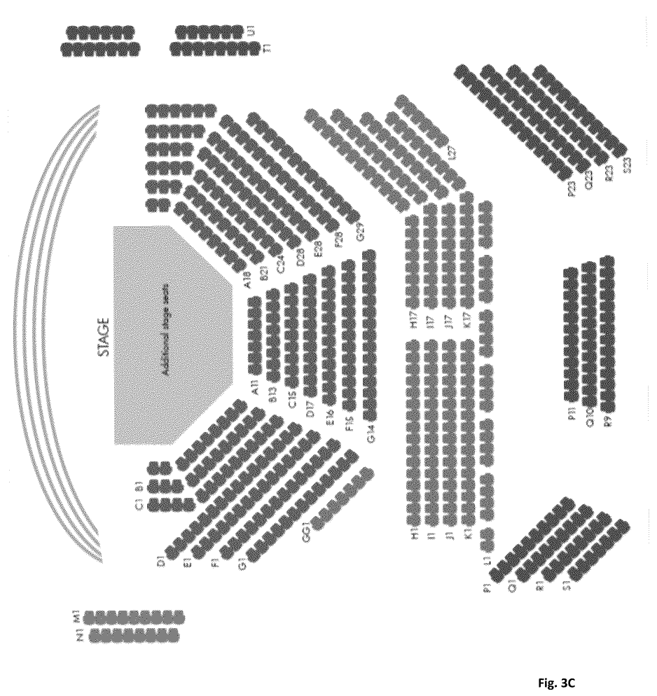

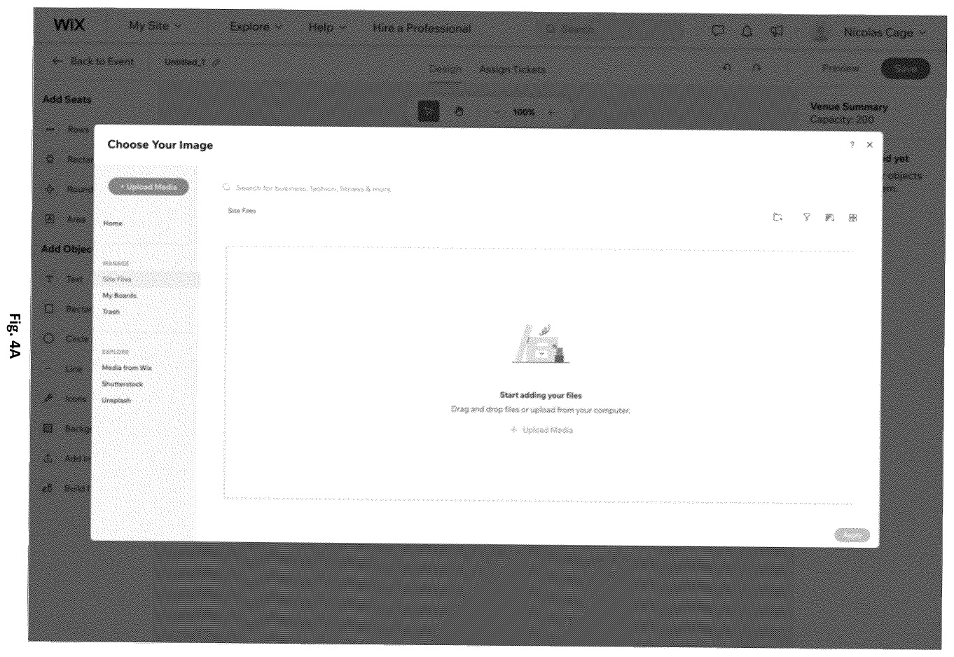

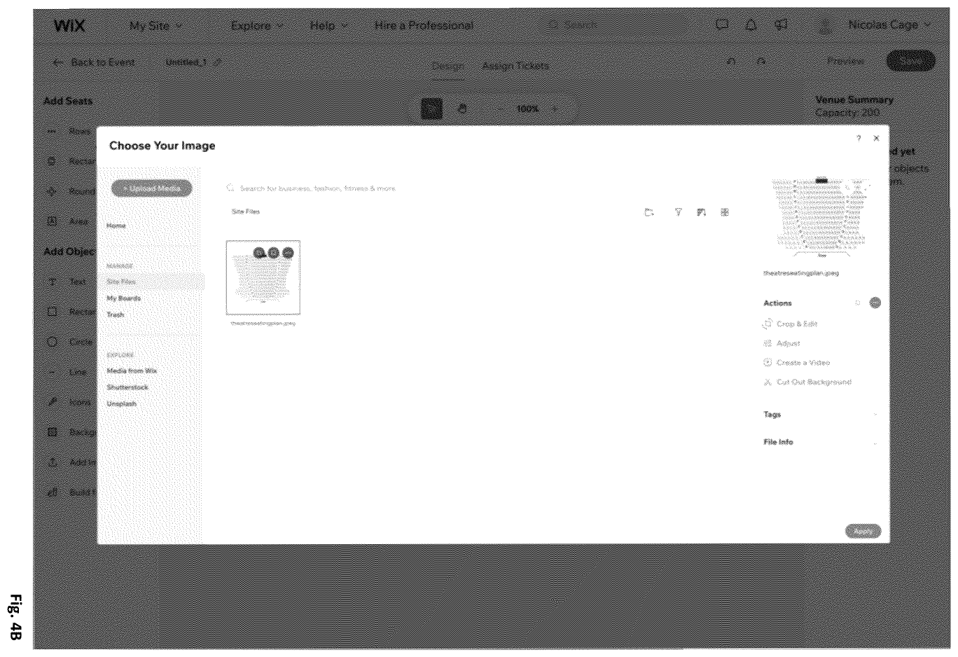

Turning to FIG. 2A, we see a non-vectorized visual representation in the form of a photo of an exemplary concert venue, including a piano, stage and seating placed around the stage. FIG. 2B shows a flowchart including the steps of converting the virtual representation of FIG. 2A into a vectorized representation of the venue with various venue features, including seats, labeled and optionally grouped as shown in FIG. 2D. FIG. 3C illustrates an intermediate state edge-detected image to be ocr'd or compute vision feature extracted and feature classified in accordance with embodiments of the present invention.

FIGS. 3A to 3C illustrate a set of screens for a system in accordance with embodiment of the present invention wherein a venue representation is drawn, otherwise produced and or edited by a user using authoring functionality provided by the system through a web interface. FIG. 3C shows a computer assisted venue representation showing venue elements in vector form and row designations assigned to different searing rows.

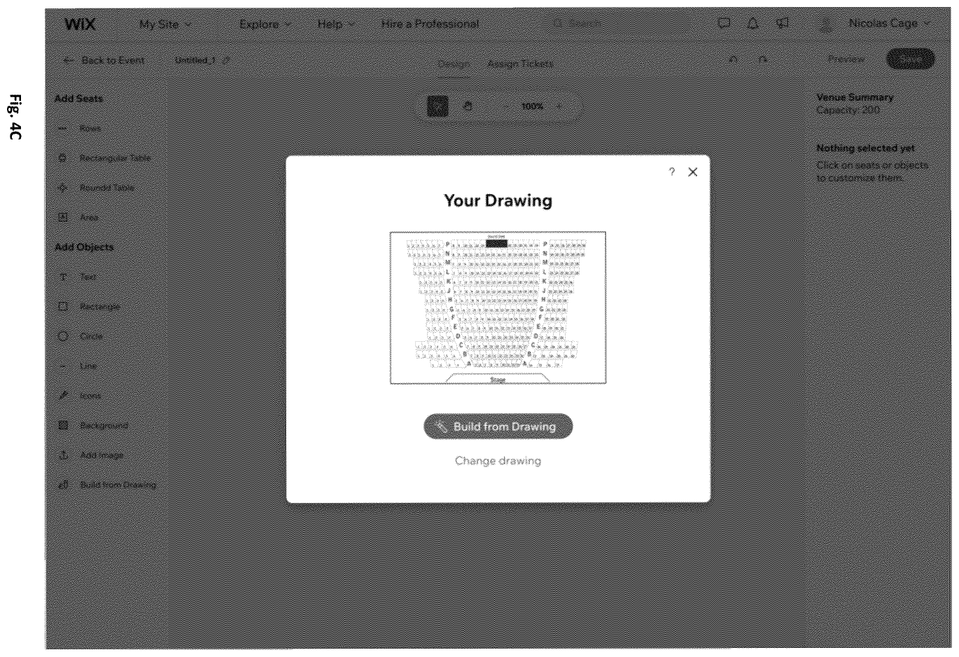

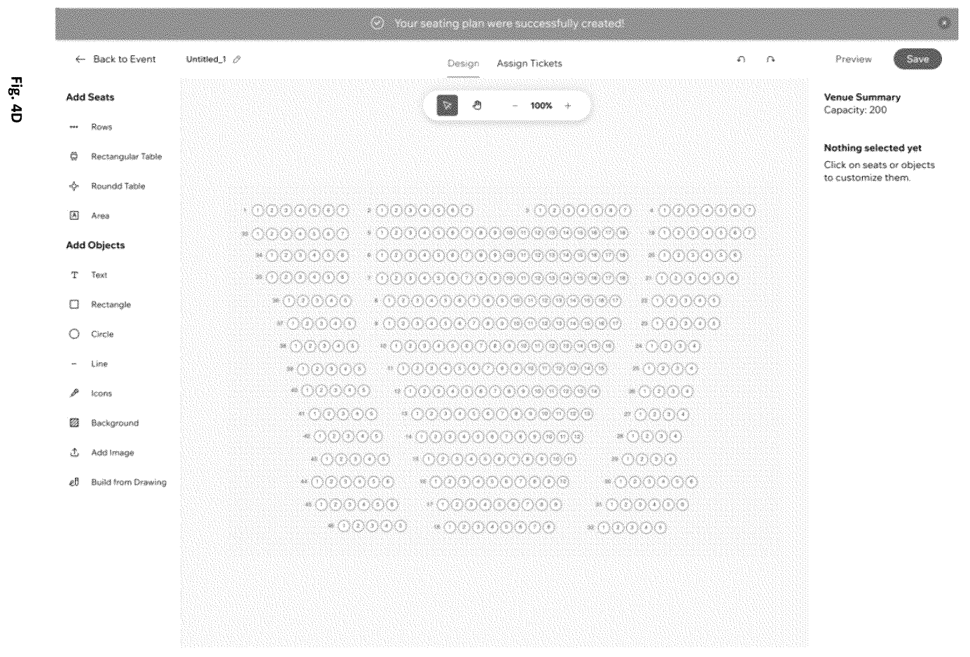

FIGS. 4A to 4C illustrate a set of screens of an exemplary system in accordance with embodiment of the present invention, wherein a venue representation is provided in the form of an uploaded file. The upload venue representation is processed and converted into a seating plan using the computer vision and AI capabilities embedded within system in accordance with embodiments of the present invention. A user interacts with a web-based authoring interface to provide the system with one or more venue representations, along with additional venue and or event related information, such as for example seating plan preferences parameters. FIG. 4D shows a computer-generated venue seating plan proposal in accordance with embodiments of the present invention. This plan proposal can be edited manually or iteratively regenerated with adjusted generation parameters.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed:

1. A system for generating a digital seating plan for a given event at a given venue, said system comprising:
an input module to receive and analyze a visual representation of the venue; and
a Seating Plan Generator Module (“SPGM”) utilizing at least one of a set of seat plan generator algorithms, to autogenerate a seating plan for the given event venue combination based on: (1) physical constraints identified within said visual representations; and (2) user selected priorities regarding a least one feature of the seating plan.

2. The system according to claim 1, further comprising a parser functionally associated with said input module and configured to determine whether a received visual representation of a venue is vectorized, and further including a vectorization module to vectorize visual representations of venues received in a non-vectorized format.

3. The system according to claim 2, wherein non-vectorized visual representations of a specific venue may be of a format selected from the group consisting of handmade sketches, video recordings and photographs of the venue.

4. The system according to claim 1, wherein said seating plan module is functionally associated with a Venue Feature Classifier (“VFC”) to identify and location-register venue features including one or more of: (a) fixed columns and other structural supports within the venue, (b) existing seats and other seating structures within the venue, (c) stages or platforms towards which seated event attendees should be facing.

5. The system according to claim 4, wherein said SPGM generates seat identifiers for existing seats registered by said VFC.

6. The system according to claim 4, wherein said SPGM generates at least one new seat proposal along with corresponding location coordinates utilizing a user selected algorithm as constrained by placement of venue features identified and registered by said VFC from a venue visual representation.

7. The system according to claim 6, wherein new seat proposals generated by said SPGM are issued seat identifiers along with corresponding venue location coordinates.

8. The system according to claim 7, wherein said SPGM is functionally associated with an Event Ticking system configured to enable the public to purchase designed tickets proposed.

9. The system according to claim 1, wherein said system is integral or otherwise functionally associated with an online website builder.

10. A website builder comprising:
a module that receives and embeds into a website data or a link associated with an algorithmically generated digital seating plan.

11. The website builder of claim 10, further including a processing platform to algorithmically generate a digital seating plan.

12. The website builder of claim 11, wherein said processing platform:
an input module to receive and analyze a visual representation of the venue; and
a Seating Plan Generator Module (“SPGM”) utilizing at least one of a set of seating plan generator algorithms, to autogenerate a seating plan for the given event venue combination based on: (1) physical constraints identified within said visual representations; and (2) user selected priorities regarding at least one feature of the seating plan.

13. The website builder according to claim 12, further comprising a parser functionally associated with said input module and configured to determine whether a received visual representation of a venue is vectorized, and further including a vectorization module to vectorize visual representations of venues received in a non-vectorized format.

14. The website builder according to claim 13, wherein non-vectorized visual representations of a specific venue may be of a format selected from the group consisting of handmade sketches, video recordings and photographs of the venue.

15. The website builder according to claim 12, wherein said seating plan module is functionally associated with a Venue Feature Classifier (“VFC”) to identify and location-register venue features including one or more of: (a) fixed columns and other structural supports within the venue, (b) existing seats and other seating structures within the venue, (c) stages or platforms towards which seated event attendees should be facing.

16. The website builder according to claim 15, wherein said SPGM generates seat identifiers for existing seats registered by said VFC.

17. The website builder according to claim 15, wherein said SPGM generates at least one new seat proposal along with corresponding location coordinates utilizing a user selected algorithm as constrained by placement of venue features identified and registered by said VFC from a venue visual representation.

18. The website builder according to claim 17, wherein new seat proposals generated by said SPGM are issued seat identifiers along with corresponding venue location coordinates.

19. The website builder according to claim 18, wherein said SPGM is functionally associated with an Event Ticking system configured to enable the public to purchase designed tickets proposed.
